(19) United States
(12) Patent Application Publication
(10) Pub. No.: US 2026/0076127 A1
(43) Pub. Date: Mar. 12, 2026

(54) SEMICONDUCTOR PACKAGE AND SMICONDUCTOR PACKAGE MANUFACTURING METHOD

(71) Applicant: NEPES CO., LTD., Chungcheongbuk-do (KR)

(72) Inventor: Hyungjin Shin, Chungcheongbuk-do (KR)

(21) Appl. No.: 19/108,409

(22) PCT Filed: Sep. 5, 2023
(86) PCT No.: PCT/KR2023/013267

§ 371 Date: Mar. 3, 2025

(30) Foreign Application Priority Data
Sep. 5, 2022 (KR) 10-2022-0112349
Sep. 5, 2022 (KR) 10-2022-0112350

(51) Int. Cl. H01L 21/78; H01L 21/66; H01L 23/00

(52) U.S. Cl. CPC H10P 54/00; H10P 74/207; H10W 70/09; H10W 72/0198; H10W 90/10

(57) ABSTRACT

A technical idea of a present invention provides a method for manufacturing a semiconductor package, comprising: a step of disposing a plurality of dies on a carrier while being spaced apart from each other in a horizontal direction; a first sawing step of sawing the carrier to separate the carrier into a plurality of sub-panels on which the plurality of dies are disposed; a step of testing the dies; and a second sawing step of sawing between each of the dies of the sub-panels to separate the sub-panels into individual semiconductor packages; wherein the carrier includes a plurality of first regions in which the dies are disposed and a second region in which the dies are not disposed, and wherein a first horizontal distance from a side of the carrier to the first region is smaller than a second horizontal distance from the first region to the first region.

### TECHNICAL FIELD

The present invention relates to a semiconductor package and a method of manufacturing a semiconductor package, and more particularly, to a method of manufacturing a wafer level package.

### BACKGROUND ART

Since A total cost of semiconductors is rising and as there is a limit to reducing a cost of a front-end process, the need to reduce a cost in a packaging process, which is a back-end process, is increasing. In addition, a number of input/output (I/O) terminals required for semiconductors is increasing due to a high performance of various mobile devices.

In this situation, a wafer level package technology, which performs the semiconductor package process at a wafer level and separates the semiconductor package of the wafer level that have undergone the semiconductor package process into individual units is attracting attention. Fan-Out Wafer Level Package (FOWLP) or Fan-Out Panel Level Package (FOPLP) is a technology that directly mounts a chip on a wafer, not a PCB. According to FOWLP and FOPLP, it is possible to reduce a manufacturing cost of semiconductor packages as much as PCB is not used, and to miniaturize semiconductor packages, improve heat dissipation functions, reduce power consumption, and improve frequency band.

FOWLP or FOPLP is implemented as a package by reconstructing individual dies into a wafer shape on a carrier, molding them, and then performing a redistributed (RDL) process and bumping process in a fan-out type.

### DISCLOSURE

### Technical Problem

An object of a present invention is to provide a semiconductor package with improved structural stability and a method of manufacturing a semiconductor package.

Another technical object of the present invention is to provide a semiconductor package with improved warpage control capability and a method of manufacturing a semiconductor package.

### Technical Solution

In order to solve the above-described problem, a technical idea of a present invention may provide a method for manufacturing a semiconductor package, comprising: a step of disposing a plurality of dies on a carrier while being spaced apart from each other in a horizontal direction; a first sawing step of sawing the carrier to separate the carrier into a plurality of sub-panels on which the plurality of dies are disposed; a step of testing the dies; and a second sawing step of sawing between each of the dies of the sub-panels to separate the sub-panels into individual semiconductor packages; wherein the carrier includes a plurality of first regions in which the dies are disposed and a second region in which the dies are not disposed, and wherein a first horizontal distance from a side of the carrier to the first region is smaller than a second horizontal distance from the first region to the first region.

The first sawing step may be performed by sawing along a first scribe lane provided in the second region.

The first horizontal distance from the side of the carrier to the first region may be smaller than a third horizontal distance from the first region to a side of the sub-panel relatively close to the first scribe lane.

When viewed from a planar perspective, the sub-panel may have the first region surrounded by the second region.

The carrier is divided into the plurality of sub-panels, and at least two of the plurality of sub-panels have different horizontal areas.

In order to solve the above-described problem, another technical idea of a present invention may provide a semiconductor package comprising a carrier; an adhesive layer disposed on the carrier; and a plurality of dies disposed on the adhesive layer and bonded by the adhesive layer; and wherein the carrier includes a plurality of first regions in which the dies are disposed and a second region in which the dies are not disposed, and wherein a horizontal distance from a side of the carrier to the first region is smaller than a horizontal distance from the first region to the first region.

In order to solve the above-described problem, another technical idea of a present invention may provide a semiconductor package manufacturing method comprising: a step of disposing a plurality of dies and dummy dies on a carrier while being spaced apart from each other; a first sawing step of sawing the carrier to separate the carrier into sub-panels on which the plurality of dies and dummy dies are disposed; a step of testing the dies; and a second sawing step of sawing between each die of the sub-panels to separate the sub-panels into individual semiconductor packages; and, wherein the carrier includes a plurality of first regions in which the die is disposed and second regions in which the die is not disposed, and wherein the dummy dies are disposed adjacent to a side of the first region.

A horizontal area of the dummy die may be different from a horizontal area of the die.

When viewed from a planar perspective, the dummy dies may be disposed to surround the dies inside the sub-panel and along at least one side of the sub-panel.

The dummy dies may be disposed along a side of the carrier.

The dummy dies may be disposed inside the sub-panel to form one or more rows or columns.

In order to solve the above-described problem, another technical idea of a present invention may provide a semiconductor package comprising: a carrier; an adhesive layer disposed on the carrier; and a plurality of dies and dummy dies disposed on the adhesive layer and bonded by the adhesive layer; and wherein the carrier includes a plurality of first regions in which the dies and dummy dies are disposed and a second region in which the dies are not disposed, and wherein the dummy dies are disposed adjacent to at least one side of the first region.

When viewed from a planar perspective, the second region may be surrounded the first region inside the sub-panel, and the dummy dies may be disposed along a side of the carrier.

When viewed from a planar perspective, the dummy dies may be disposed along at least two sides of the first region inside the first region.

### Advantageous Effects

The semiconductor package and the method for manufacturing the semiconductor package according to the present invention can secure an area of a second region surrounding a first region in which dies are disposed, thereby improving structural stability of the semiconductor package.

In addition, the semiconductor package and the method for manufacturing the semiconductor package according to the present invention can improve warpage control capability of the semiconductor package by arranging a dummy die adjacent to a side of the first region in which the dies are disposed.

In addition, the semiconductor package and the method for manufacturing the semiconductor package according to the present invention can improve structural stability of the semiconductor package by having a dummy die surround a semiconductor die.

### DESCRIPTION OF DRAWINGS

FIG. 1a is a layout view of a semiconductor package according to embodiments of a present invention, and FIG. 1b is a cross-sectional view of the semiconductor package according to embodiments of the present invention. FIG. 1c is a layout view showing a state in which a semiconductor package is separated into sub-panels by a first sawing.

FIG. 2 is a layout view of a semiconductor package according to embodiments of the present invention.

FIG. 3 is a cross-sectional view of a semiconductor package according to embodiments of the present invention.

FIGS. 4a to 4e are cross-sectional views illustrating a method of manufacturing a semiconductor package according to embodiments of the present invention.

FIGS. 5a to 5d are cross-sectional views illustrating a method of manufacturing a semiconductor package according to embodiments of the present invention.

FIG. 6 is a layout view of a semiconductor package according to embodiments of the present invention.

FIG. 7a is a layout view of a semiconductor package according to embodiments of the present invention, and FIG. 7b is a cross-sectional view of the semiconductor package according to embodiments of the present invention. FIG. 7C is a layout view illustrating a state in which a semiconductor package is separated into sub-panels by a first sawing.

FIG. 8 is a layout view of a semiconductor package according to embodiments of the present invention.

FIG. 9 is a cross-sectional view of a semiconductor package according to embodiments of the present invention.

FIGS. 10a to 10e are cross-sectional views illustrating a method of manufacturing a semiconductor package according to embodiments of the present invention.

FIGS. 11a to 11d are cross-sectional views illustrating a method of manufacturing a semiconductor package according to embodiments of the present invention.

FIG. 12 is a layout view of a semiconductor package according to embodiments of the present invention.

FIG. 13 is a layout view of a semiconductor package according to embodiments of the present invention.

FIG. 14 is a layout view of a semiconductor package according to embodiments of the present invention.

FIG. 15 is a layout view of a semiconductor package according to embodiments of the present invention.

FIG. 16 is a cross-sectional view illustrating a process of a method for manufacturing a semiconductor package according to embodiments of the present invention.

FIG. 17 is a cross-sectional view illustrating a process of a method of manufacturing a semiconductor package according to embodiments of the present invention.

FIG. 18 is a cross-sectional view illustrating a process of a method for manufacturing a semiconductor package according to embodiments of the present invention.

FIG. 19 is a cross-sectional view illustrating a process of a method of manufacturing a semiconductor package according to embodiments of the present invention.

### BEST MODEL

A method for manufacturing a semiconductor package according to an embodiment comprises a step of disposing a plurality of dies on a carrier while being spaced apart from each other in a horizontal direction; a first sawing step of sawing the carrier to separate the carrier into a plurality of sub-panels on which the plurality of dies are disposed; a step of testing the dies; and a second sawing step of sawing between each of the dies of the sub-panels to separate the sub-panels into individual semiconductor packages; wherein the carrier includes a plurality of first regions in which the dies are disposed and a second region in which the dies are not disposed, and wherein a first horizontal distance from a side of the carrier to the first region is smaller than a second horizontal distance from the first region to the first region.

### Mode for the Invention

Hereinafter, embodiments of the present invention will be described in detail with reference to accompanying drawings so that those skilled in the art may easily implement the present invention. The present invention may be implemented in a number of different forms and is not limited to the embodiments described herein. In order to clearly describe the present invention, parts irrelevant to the description are omitted from the drawings, and same reference numerals are added to identical or similar components throughout the specification.

In this specification, the terms “include” or “have” are intended to describe the presence of features, numbers, steps, operations, components, parts, or combinations thereof described in the specification, but should be understood as not excluding in advance the possibility of the presence or addition of one or more other features, numbers, steps, operations, components, parts, or combinations thereof.

In this specification, spatially relative terms such as “front”, “rear”, “upper”, or “lower” may be used to describe the relationship with components depicted in the drawings. These are relative terms determined based on what is depicted in the drawings, and a positional relationship may be interpreted in the opposite way depending on an orientation.

When a component is disposed “front”, “rear”, “upper”, or “lower” another component, it includes not only being disposed “front”, “rear”, “upper”, or “lower” another component, but also having another component is disposed therebetween, unless there are special limitations. In addition, when a component is “connected” to another component, it includes not only being directly connected to each other, but also being indirectly connected to each other, unless there are special limitations.

A method for manufacturing a semiconductor package according to embodiments of the present invention can be applied to a wafer-level package. A method for manufacturing a semiconductor package according to embodiments of the present invention allows a semiconductor package to be manufactured without using a PCB substrate. The embodiments of the present invention can be applied to a fan-out panel level package (FOPLP).

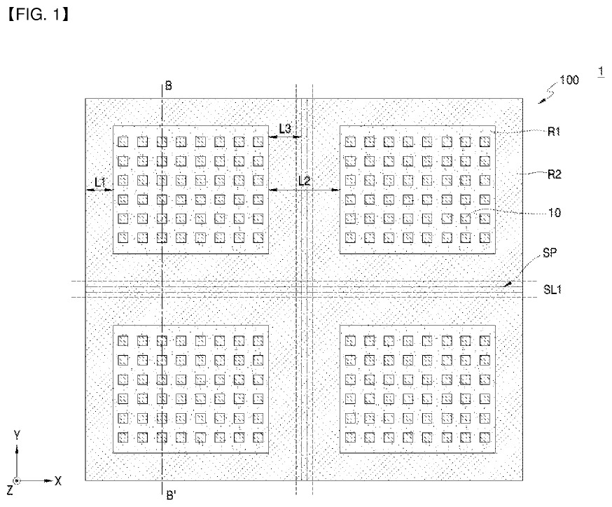

FIG. 1a is a layout view of a semiconductor package according to embodiments of the present invention, and FIG. 1b is a cross-sectional view of a semiconductor package according to embodiments of the present invention, specifically, a cross-sectional view taken along line B-B′ of FIG. 1a. In addition, FIG. 1c is a layout view showing a state in which a semiconductor package is separated into sub-panels by a first sawing. In FIG. 1b, for convenience of explanation, a case in which two dies are disposed in each first region R1 is illustrated as an example.

Referring to FIGS. 1a to 1c, a semiconductor package 1 may include a carrier 100, an adhesive layer 110 disposed on the carrier 100, and a plurality of dies 10 disposed on the adhesive layer 110. In addition, the semiconductor package 1 may include a plurality of sub-panels SP.

In FIG. 1a, four sub-panels SP are illustrated as being disposed on one carrier 100 as an example, but the number of sub-panels SP disposed on one carrier 100 may be variously modified. In some embodiments, one semiconductor package 1 may include three or fewer sub-panels SP or five or more sub-panels SP.

A die 10 may be disposed on the carrier 100 in a plurality of rows and columns. The die 10 may include a connection part 11 for input/output connection with an outside. For example, the connection part 11 may be a pad. In addition, the connection part 11 may be electrically connected to a post (20, pillar). The post 20 may include copper, for example. The die 10 may be mounted on a surface of the carrier 100 in a PnP (Pick and Place) manner.

The carrier 100 may be formed in a panel shape. The carrier 100 may be referred to as a main panel, for example. For example, it is desirable for the carrier 100 to have a property that can withstand pressure during molding. For example, the carrier 100 may be a glass panel, i.e., a glass substrate having a square frame. For example, the carrier may be a glass substrate measuring 600 mm*600 mm. According, when a panel is used as a carrier 100, more dies 10 can be packaged in one carrier 100.

For example, the carrier 100 can be made of Alloy 42 material. Alloy 42 can be a special performance alloy (SPA: Special Performance Alloys) with a low coefficient of thermal expansion over a certain temperature range and a limited coefficient.

From a planar perspective, the carrier 100 can include a first region R1 in which the die 10 is disposed and a second region R2 in which the die 10 is not disposed. The first region R1 can include an active region, and the second region R2 can include a handling region and a sawing region.

The active region can mean a region where a die 10 and/or a dummy die 12 are mounted. The handling region refers to a non-active region and may be referred to as a marking region. The sawing region may be referred to as a cutting region and/or a separation region.

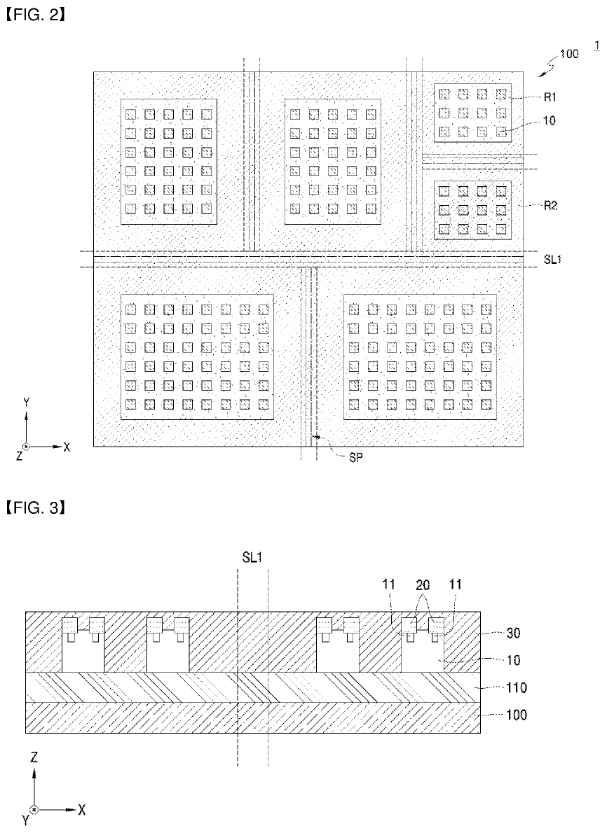

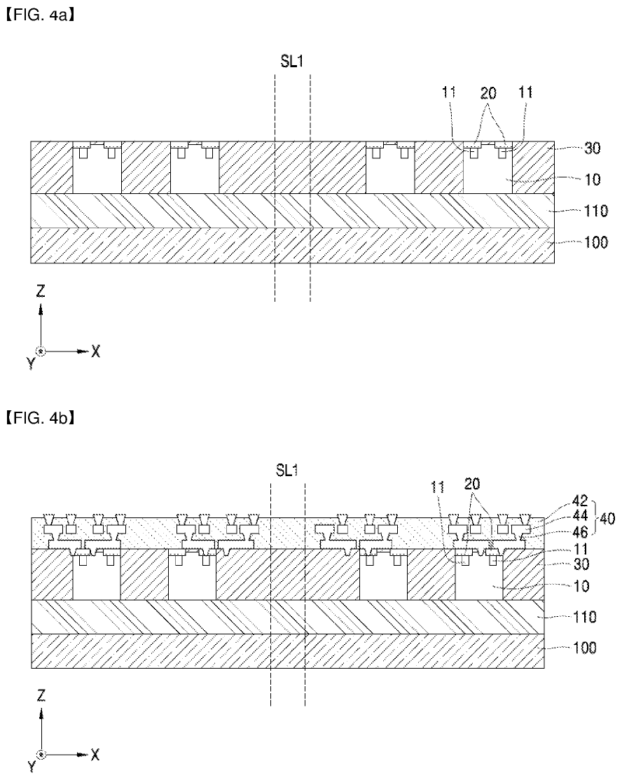

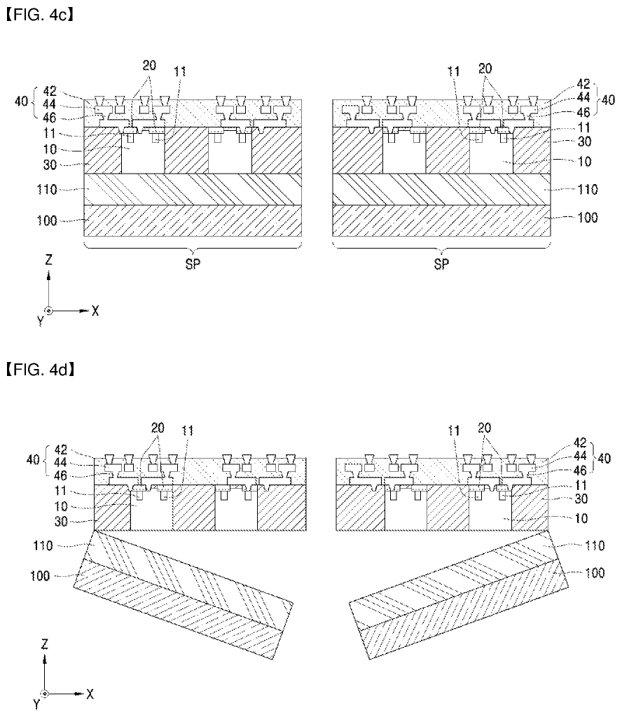

The carrier 100, i.e., the main panel, may be sawed and separated into a plurality of sub-panels SP. After that, the sub-panels SP include an active region and a handling region, and later, the die 10 of the active region may be individually divided to form a unit semiconductor package (2 of FIG. 4e).

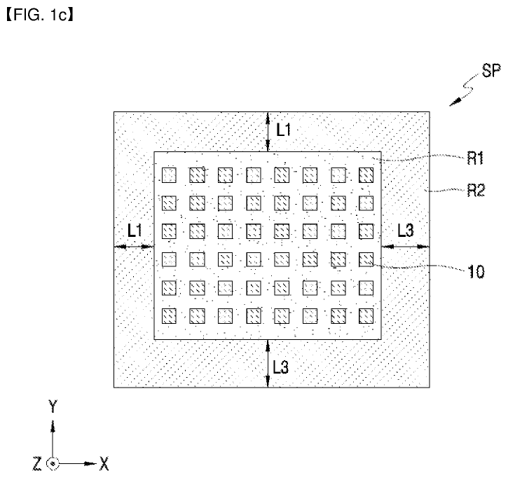

From a planar perspective, a first scribe lane (scribe lane, SL1) may be disposed inside the second region R2. The carrier 100 may be cut along the first scribe lane SL1 so that the semiconductor package 1 may be separated into a plurality of sub-panels SP. From a planar perspective, a second scribe lane (not shown) may be disposed inside the first region R1. Along the second scribe lane (not shown), the sub-panels SP may be separated into individual semiconductor packages (2 of FIG. 3e).

The adhesive layer 110 may be formed by applying an adhesive on the carrier 100. The adhesive layer 110 may attach the die 10 and the carrier 100 to each other. For another example, the adhesive layer 110 may be formed by tape lamination. For another example, the adhesive layer 110 may be heated and adhered to the carrier 100.

A first horizontal distance L1 from a side of the carrier 100 to the first region R1 may be smaller than a second horizontal distance L2 between the plurality of first regions R1. When the first horizontal distance L1 from a side of the carrier 100 to the first region R1 is smaller than a second horizontal distance L2 between the plurality of first regions R1, the first region R1 may be sufficiently surrounded by the second region R2 after sawing the carrier 100, and accordingly, it may be easier to handle the sub-panel SP. For example, the second horizontal distance L2 may be a value greater than twice the first horizontal distance L1.

In addition, the first horizontal distance L1 from a side of the carrier 100 to the first region R1 may be smaller than a third horizontal distance L3 from a side of the first region R1 to a side of a sub-panel SP relatively close to the first scribe lane SL1.

The first to third horizontal distances L1, L2, and L3 may mean distances extending parallel to a first horizontal direction, a second horizontal direction (X direction, Y direction) and/or a diagonal direction.

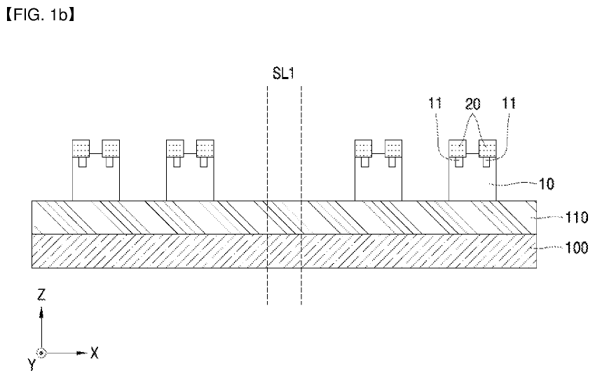

FIG. 2 is a layout view of a semiconductor package according to embodiments of the present invention.

Referring to FIG. 2, the semiconductor package 1a of the present embodiment may include a plurality of sub-panels SP having different horizontal areas. In FIGS. 1a to 1c, horizontal areas of each sub-panel SP are illustrated as being the same, but referring to FIG. 2, horizontal areas of each sub-panel SP may be different. That is, horizontal areas of at least two sub-panels SP among the plurality of sub-panels SP may be different from each other.

The horizontal area of the sub-panels SP may be variously modified depending on a horizontal area (size) of the die 10 and/or a horizontal area (size) of the dummy die 12, a pattern of the redistributed layer (40 of FIG. 4a) and/or a mask.

FIG. 3 is a cross-sectional view of a semiconductor package according to embodiments of the present invention, specifically, a cross-sectional view showing a molding layer disposed on the semiconductor package of FIGS. 1a to 1c.

Referring to FIG. 3, a molding layer 30 may be disposed on the adhesive layer 110 to surround a side surface of the die 10 and an upper surface of the die 10 (Front-Mold). That is, the molding layer 30 may surround the connection part 11 of the die 10. The molding layer 30 may include, for example, an epoxy resin.

FIGS. 4a to 4e are cross-sectional views showing a method for manufacturing a semiconductor package according to embodiments of the present invention. Specifically, in the method for manufacturing the semiconductor package of FIGS. 4a to 4e, a first sawing process is performed while the die 10 and carrier 100 are attached.

Referring to FIGS. 3 and 4a, an upper surface of the molding layer 30 of the semiconductor package of FIG. 3 may be ground. Here, a lower surface of the molding layer 30 may mean a surface directly in contact with the adhesive layer 110, and an upper surface of the molding layer 30 may mean a surface opposite to the lower surface of the molding layer 30.

Since the upper surface of the molding layer 30 is ground, an upper surface of the die 10 and an upper surface of the molding layer 30 may be positioned at substantially a same vertical level. Here, the lower surface of the die 10 may mean a surface closest to the adhesive layer 110, and an upper surface of the die 10 may mean the surface opposite to the lower surface of the die 10. In a process of grinding the upper surface of the molding layer 30, a part of the post 20 may also be ground. Therefore, the post 20 of the die 10 may be exposed to an outside.

Referring to FIGS. 4a and 4b, a redistributed process may be performed on an entire surface where the post 20 of the die 10 is exposed. That is, a redistributed layer (RDL, 40) may be formed on an upper surface of the die 10. The redistributed layer 40 may include an insulating layer 42, a redistributed line 44, and a conductive via 46. The insulating layer 42 may be formed of an insulating material, for example, a PID (Photo-Imageable Dielectric) resin, and may further include an inorganic filler. The insulating layer 42 may have a multi-layer structure according to a multi-layer structure of the redistributed line 44. The redistributed line 44 may be formed of multiple layers and may be connected to each other by a conductive via 46.

The conductive via 46 may be configured to transmit an electrical signal and/or heat within the semiconductor package 1. The conductive via 46 may be a metal such as molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof, but is not limited thereto. The conductive via 46 may be manufactured by performing a process of exposing a photosensitive insulating material and a process of developing the photosensitive insulating material.

Referring to FIGS. 1a, 1c, 4b and 4c, the semiconductor package 1 can be separated into a plurality of sub-panels SP through a first sawing. In the present embodiment, the first sawing is performed while the carrier 100 is attached. The first sawing can be performed along the first scribe lane SL1, and in a planar view, the first scribe lane SL1 can be disposed in the second region R2 of the carrier 100.

Referring to FIGS. 4c and 4d, after the die 10 of the sub-panel SP is tested through the conduction of the redistributed layer 40, the carrier 100 and the adhesive layer 110 may be separated from the die 10 (Carrier De-bond).

Referring to FIGS. 1a, 1c, 4d and 4e, the sub-panel SP can be second-sawed as an unit of individual semiconductor package 2. In a planar view, the second sawing can be performed along a second scribe lane (not shown) inside the first region R1. The second scribe lane (not shown) can extend between a plurality of dies 10.

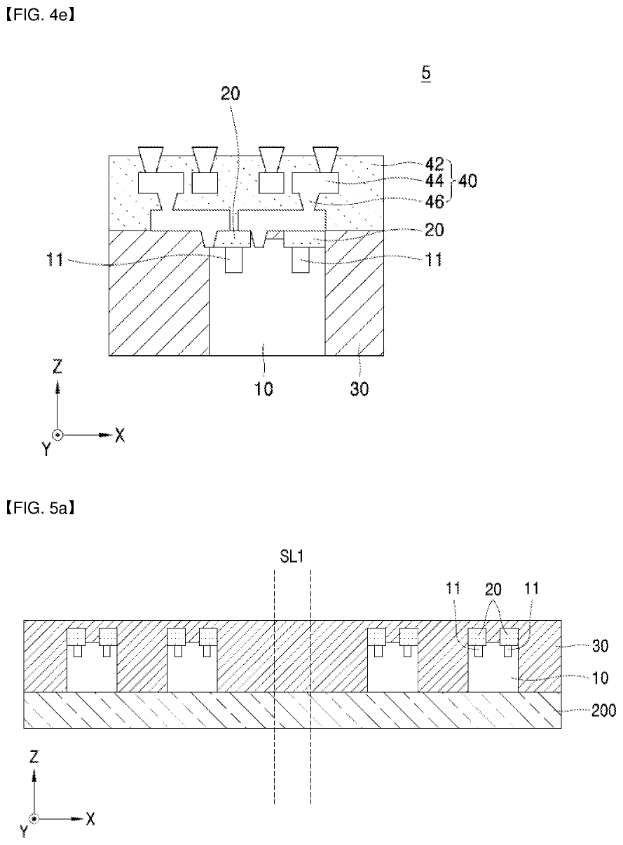

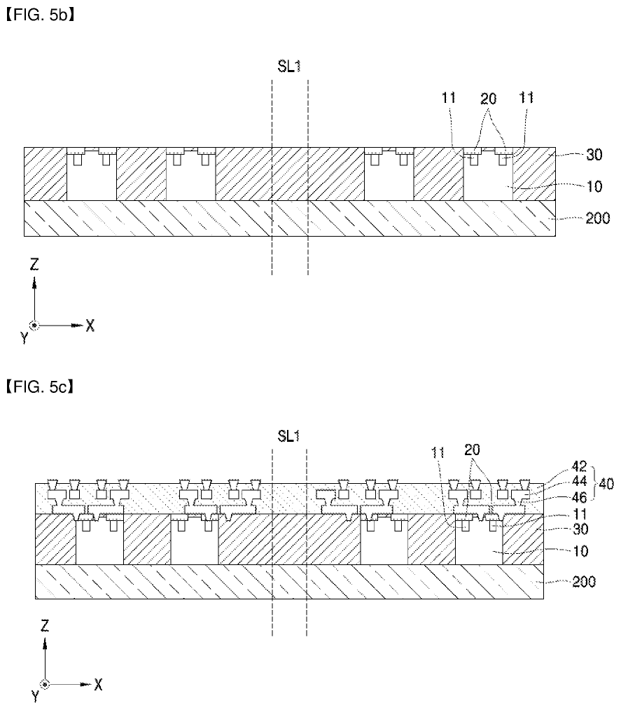

FIGS. 5a to 5d are cross-sectional views illustrating a method for manufacturing a semiconductor package according to embodiments of the present invention. Specifically, in the semiconductor package manufacturing method of FIGS. 5a to 5d, the carrier 100 and the adhesive layer 110 are separated from the die 10, and then a first sawing is performed.

Referring to FIGS. 4 and 5a, the carrier 100 and the adhesive layer 110 of the semiconductor package 1 of FIG. 4 can be removed (Carrier De-bond). In addition, a lamination layer (Lamination layer, 200) can be disposed on the lower surface of the semiconductor package 1 from which the carrier 100 has been removed. For example, the lamination layer 200 can be disposed by attaching a BSP lamination film. In a process of removing the carrier 100 from the semiconductor package 1, a lower surface of the die 10 can be exposed, but an upper surface of the die 10 may not be exposed because the upper surface of the die 10 is molded by the molding layer 30.

Referring to FIGS. 5a and 5b, an upper surface of the molding layer 30 may be ground. Since the upper surface of the molding layer 30 is ground, the upper surface of the die 10 and the upper surface of the molding layer 30 may be substantially positioned at a same vertical level.

Referring to FIGS. 5b and 5c, a redistributed process may be performed on an entire surface where the post 20 of the die 10 is exposed. That is, a redistributed layer 40 may be formed on the upper surface of the die 10. In FIG. 5c, only one redistributed layer 40 is illustrated on the molding layer 30 as an example, but two or more redistributed layers 40 may be formed as needed.

Referring to FIGS. 1a, 1c, 5c, and 5d, the semiconductor package may be separated into sub-panels SP through the first sawing. In the present embodiment, it is illustrated that the first sawing is performed while the carrier 100 is separated from the die 10. That is, this embodiment shows that the first sawing is performed while a lamination layer 200 is attached to the die 10. The first sawing can be performed along the first scribe lane SL1, and in a planar view, the first scribe lane SL1 can be disposed in the second region R2 of the carrier 100.

Referring to FIGS. 1a, 1c, 4e, and 5d, after testing the die 10 of the sub-panel, the sub-panel SP can be second sawed as an unit of the individual semiconductor package 5. In a planar view, the second sawing can be performed along the second scribe lane (not shown) inside the first region R1. The second scribe lane (not shown) may be disposed along a region between the plurality of dies 10 within the first region R1.

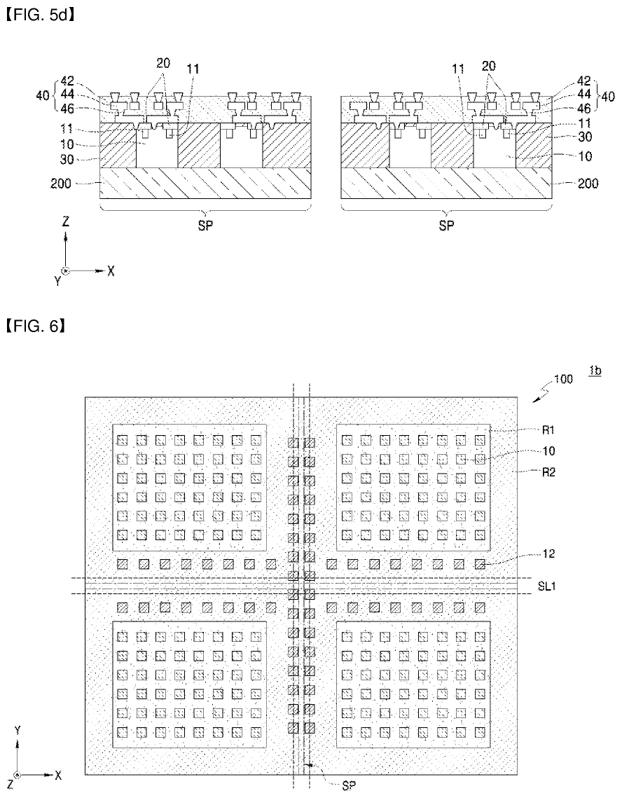

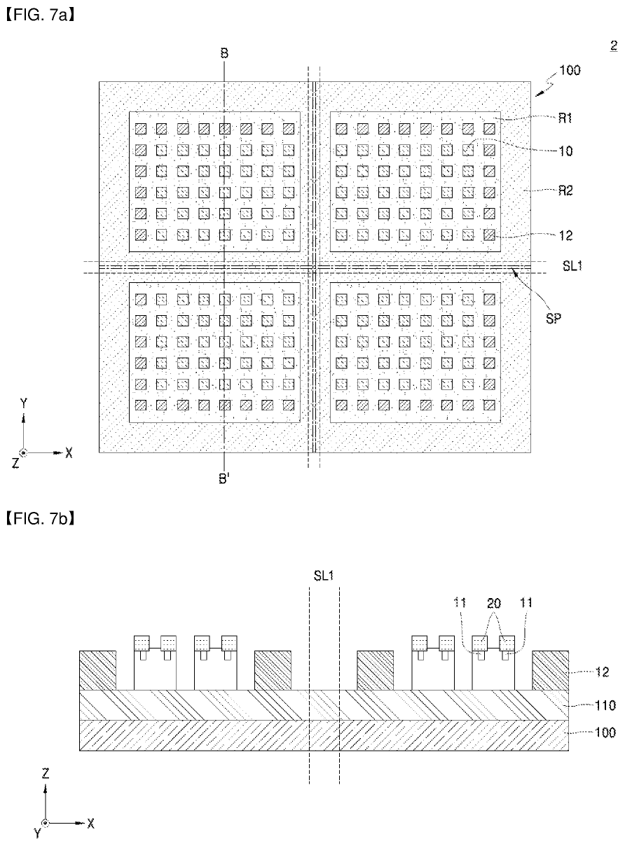

FIG. 6 is a layout view of a semiconductor package according to embodiments of the present invention.

Referring to FIG. 6, the semiconductor package 1b may include a carrier 100, a plurality of dies 10 and a dummy die 12 on the carrier 100. The carrier 100 and the plurality of dies 10 of FIG. 6 are substantially the same as the carrier 100 and the plurality of dies 10 of the semiconductor package 1 of FIGS. 1a to 1c, and only the dummy die 12 will be described here.

The dummy die 12 may be disposed in the second region R2 of the carrier 100. When a dummy die 12 is disposed in the second region R2, the rigidity of the carrier 100 can be increased, and a warpage control of the carrier 100 can be facilitated. According to one embodiment of the present invention, in a planar view, the dummy die 12 can be disposed in the handling region and/or the sawing region of the second region R2. The dummy die 12 can be removed after the first sawing and/or the second sawing. For example, the dummy die 12 can be disposed on the first scribe lane SL1 region (i.e., disposed in the sawing region), and/or the dummy die 12 can be disposed in the handling region.

For example, the dummy die 12 can mean a die without an electrical function. The dummy die 12 can be formed of a homogeneous material without any circuit, metal line, and/or sub-layer therein. The dummy die 12 may not include a test terminal and may include a dummy wafer, silicon (Si), glass, and/or quartz.

The dummy die 12 may be disposed on the carrier 100 with the die 10 in a same process, and/or the dummy die 12 may be disposed on the carrier 100 after the die 10 is first disposed on the carrier 100.

According to one embodiment of the present invention, a horizontal area of the dummy die 12 may be the same as a horizontal area of the die 10. According to another embodiment of the present invention, a horizontal area of the dummy die 12 may be different from a horizontal area of the die 10. For example, the horizontal area of the dummy die 12 may be larger than the horizontal area of the die 10. In addition, a shape of an upper surface of the dummy die 12 may be the same as and/or different from a shape of an upper surface of the fie 10.

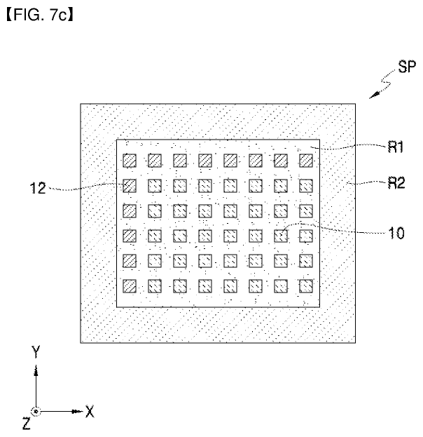

FIG. 7a is a layout view of a semiconductor package according to embodiments of the present invention, and FIG. 7b is a cross-sectional view of a semiconductor package according to embodiments of the present invention, specifically, a cross-sectional view taken along line B-B′ of FIG. 7a. In addition, FIG. 7c is a layout view showing a state in which a semiconductor package is separated into sub-panels by first sawing. In FIG. 7b, for convenience of explanation, a case in which two dies and two dummy dies are disposed in each first region R1 is illustrated as an example. The description will be made with reference to FIGS. 1 to 6 together, and the previously described content will be briefly described or omitted.

Referring to FIGS. 7a to 7c, a semiconductor package 2 may include a carrier 100, an adhesive layer 110 disposed on the carrier 100, and a plurality of dies 10 and dummy dies 12 disposed on the adhesive layer 110. In addition, the carrier 100 may include a plurality of sub-panels SP. From a planar perspective, the carrier 100 can be divided into a first region R1 where the die 10 and the dummy die 12 are disposed and a second region R2 where the die 10 and the dummy die 12 are not disposed.

The die 10 and/or the dummy die 12 may be disposed on the carrier 100 in a plurality of rows and columns. The die 10 may include a connection part 11 for input/output connection with the outside. For example, the connection part 11 may be a pad. In addition, the connection part 11 may be electrically connected to a post (20, pillar). The post 20 may include, for example, copper. The die 10 may be mounted on a surface of the carrier 100 in a PnP (Pick an Place) manner. The dummy die 12 may not include, for example, the connection part 11 and/or the post 20.

The die 10 and the dummy die 12 may be disposed in a first region R1 of the carrier 100. The dummy die 12 may be disposed adjacent to a side of the first region R1. When the dummy die 12 is disposed adjacent to a side of the first region R1, the dummy die 12 can be disposed adjacent to a side of the sub-panel SP. Accordingly, the rigidity of the sub-panel SP can be increased, and the warpage control of the sub-panel SP can be facilitated. According to embodiments of the present invention, in a planar view, the dummy die 12 can be disposed along a side of the carrier 100. Since the dummy die 12 is disposed on the first region R1, the dummy die 12 can be disposed on the carrier 100 even after the first sawing. The dummy die 12 can be removed after the second sawing.

FIG. 8 is a layout view of a semiconductor package according to embodiments of the present invention.

Referring to FIG. 8, the semiconductor package 2a of the present embodiment can include a plurality of sub-panels SP having different horizontal areas. In FIG. 7a, the horizontal area of each sub-panel SP is illustrated as being the same, but referring to FIG. 8, the horizontal area of each sub-panel SP may be different. That is, the horizontal areas of at least two sub-panels SP among the plurality of sub-panels SP may be different from each other.

The horizontal area of the sub-panel SP may be variously modified depending on a horizontal area (size) of the die 10 and/or a horizontal area (size) of the dummy die 12, a pattern of the redistributed layer 40, and/or the mask.

Even when the horizontal areas of each sub-panel SP are different, the die 10 and the dummy die 12 may be disposed in the first region R1 of the carrier 100. The dummy die 12 may be disposed adjacent to a side of the carrier 100 within the first region R1. When a dummy die 12 is disposed adjacent to a side of the carrier 100, the rigidity of the sub-panel SP can be increased, and the warpage control of the sub-panel SP can be facilitated.

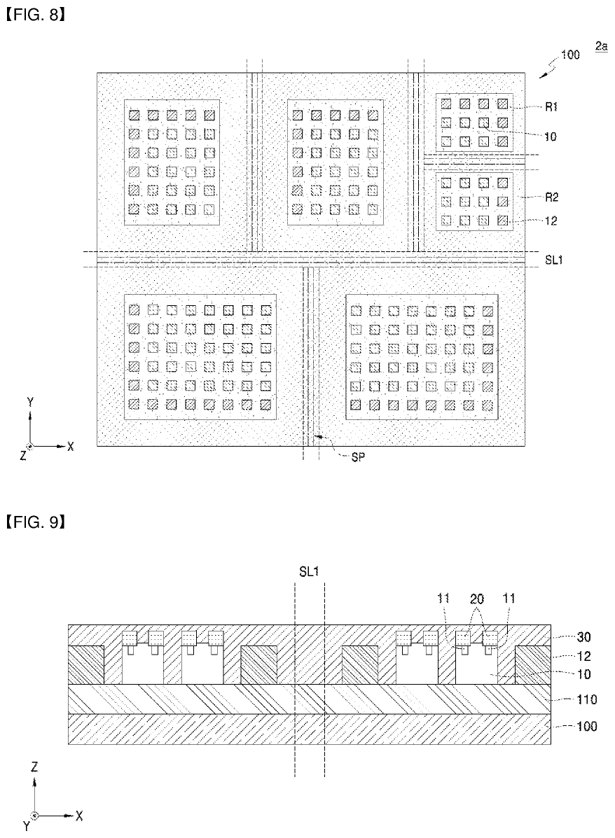

FIG. 9 is a cross-sectional view of a semiconductor package according to embodiments of the present invention, specifically, a cross-sectional view showing a molding layer disposed on the semiconductor package of FIGS. 7a to 7c.

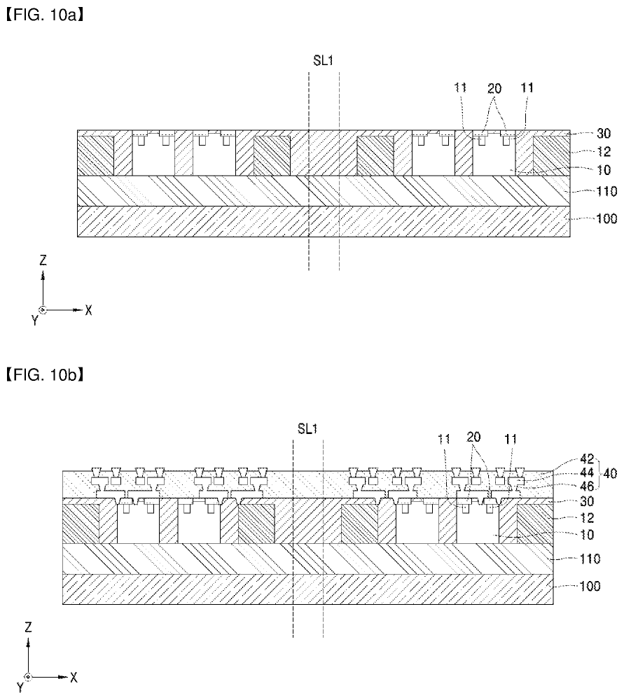

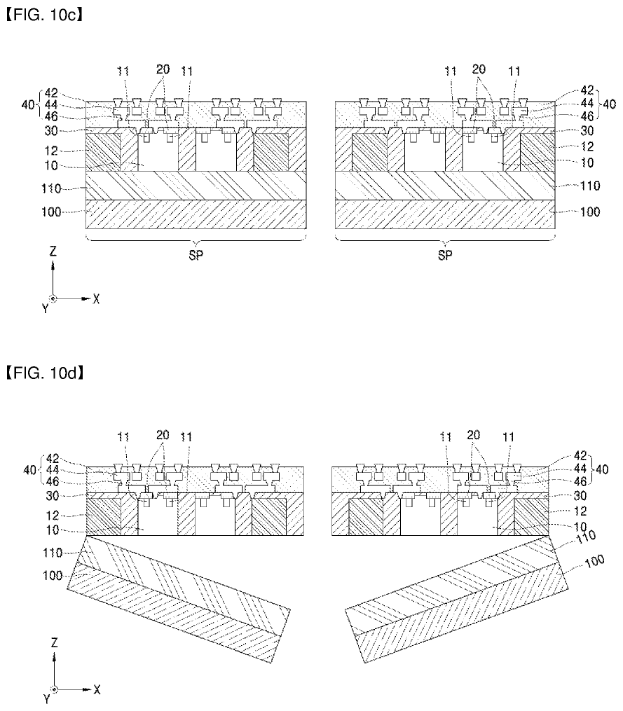

FIGS. 10a to 10e are cross-sectional views showing a method for manufacturing a semiconductor package according to embodiments of the present invention. Specifically, in the method for manufacturing a semiconductor package of FIGS. 10a to 10e, the first sawing is performed while the die 10 and the carrier 100 are attached.

Compared to the method for manufacturing a semiconductor package 5 of FIGS. 3 to 4e, a method for manufacturing a semiconductor package 5 of FIGS. 9 to 10e may further include a dummy die 12. In addition, the molding layer 30 can surround a side surface of the die 10, a side surface of the dummy die 12, an upper surface of the die 10, and an upper surface of the dummy die 12 on the adhesive layer 110. In addition, a post 20 can be formed on the die 10, and a post 20 cannot be formed on the dummy die 12. That is, the upper surface of the dummy die 12 can be in direct contact with the molding layer 30. Except for the above features, the method for manufacturing the semiconductor package 5 of FIGS. 9 to 10e can be substantially the same as the method for manufacturing the semiconductor package 5 of FIGS. 3 to 4e.

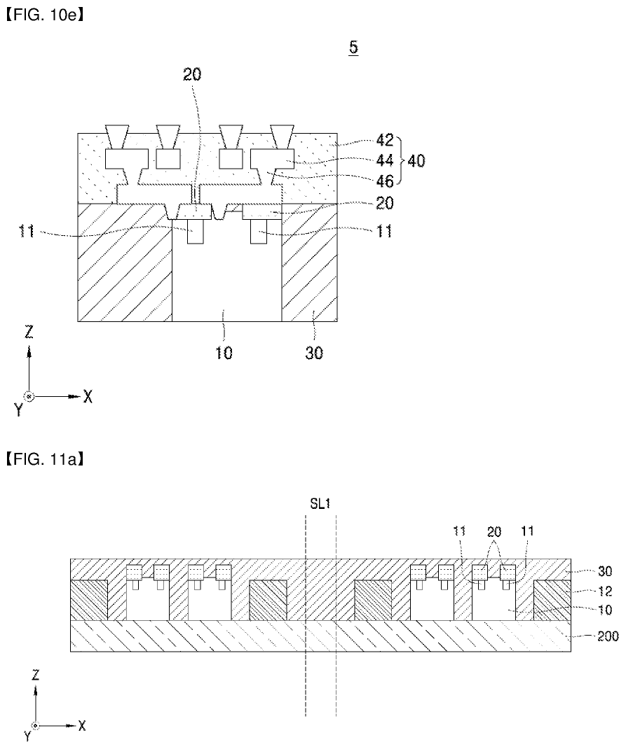

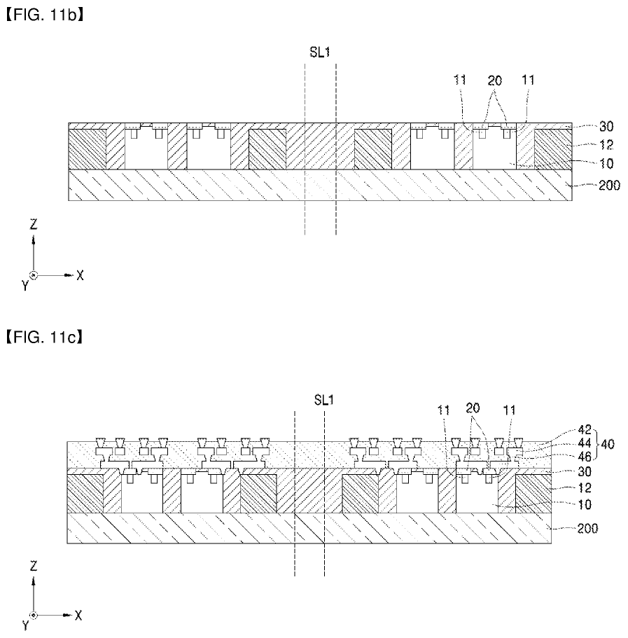

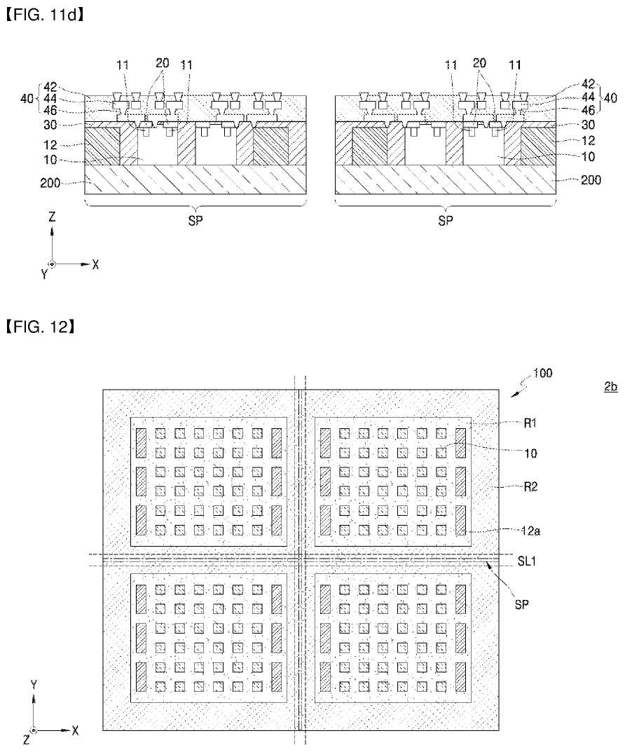

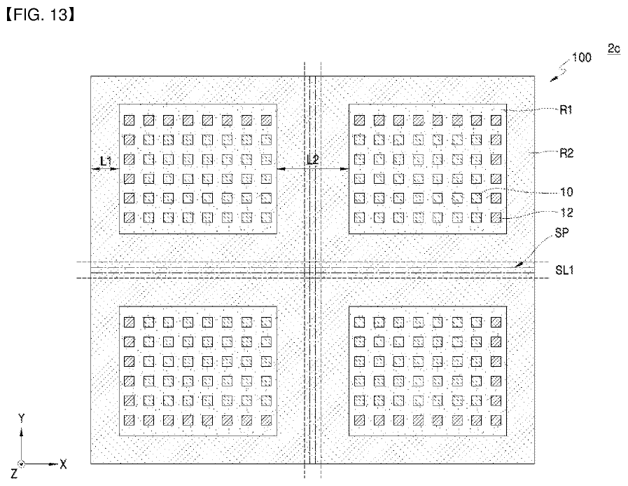

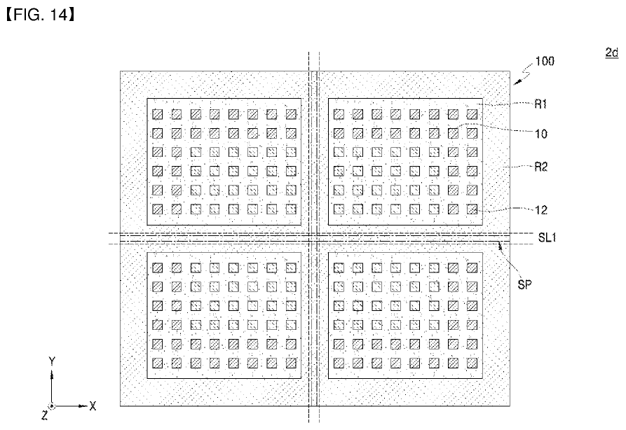

FIGS. 11a to 11d are cross-sectional views showing a method for manufacturing a semiconductor package according to embodiments of the present invention. Specifically, in the method for manufacturing the semiconductor package of FIGS. 11a to 11d, the first sawing is performed after the die 10 and the carrier 100 are separated.

Compared to the semiconductor package 5 manufacturing method of FIGS. 5a to 5d, a semiconductor package 5 manufacturing method of FIGS. 11a to 11d may further include a dummy die 12. In addition, the molding layer 30 may surround the side surface of the die 10, the side surface of the dummy die 12, the upper surface of the die 10, and the upper surface of the dummy die 12 on the adhesive layer 110. In addition, a post 20 may be formed on the die 10, and a post 20 may not be formed on the dummy die 12. That is, the upper surface of the dummy die 12 may be in direct contact with the molding layer 30. Except for the above features, the semiconductor package 5 manufacturing method of FIGS. 11a to 11d may be substantially the same as the semiconductor package 5 manufacturing method of FIGS. 5a to 5d.

FIG. 12 is a layout view of a semiconductor package according to embodiments of the present invention.

Referring to FIG. 12, the semiconductor package 2b may include a carrier 100, a plurality of dies 10 disposed on the carrier 100, and a dummy die 12a. The carrier 100 and the plurality of dies 10 of FIG. 12 are substantially the same as the carrier 100 and the plurality of dies 10 of the semiconductor package 2 of FIGS. 7a to 7c, and only the dummy die 12a will be described here.

A horizontal area of the dummy die 12a may be different from a horizontal area of the die 10. For example, the horizontal area of the dummy die 12a may be larger than the horizontal area of the die 10. In addition, a shape of the upper surface of the dummy die 12a may be the same as and/or different from a shape of the upper surface of the die 10.

In addition, the dummy die 12a may be disposed adjacent to only some of sides of the first region R1. In FIG. 12, the dummy die 12a is exemplarily illustrated as being disposed adjacent to two opposing sides of the first region R1, but the dummy die 12a may be disposed adjacent to one or more sides of the first region R1. That is, the dummy die 12a may be disposed along at least one side of the first region R1. In addition, the dummy die 12a may be disposed adjacent to only some sides of the sub-panel SP. That is, the dummy die 12a may be disposed along at least one side of the sub-panel SP.

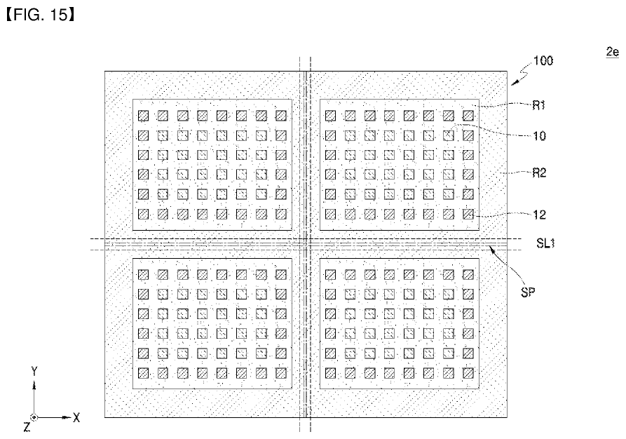

FIG. 13 is a layout view of a semiconductor package according to embodiments of the present invention.

Referring to FIG. 13, the semiconductor package 2c may include a carrier 100, a plurality of dies 10 disposed on the carrier 100, and a dummy die 12. The carrier 100, the plurality of dies 10 and the dummy dies 12 of FIG. 13 may be substantially the same as the carrier 100, the plurality of dies 10 and the dummy dies 12 of the semiconductor package 2 of FIGS. 7a to 7c.

A first horizontal distance L1 from a side of the carrier 100 to the first region R1 may be smaller than the second horizontal distance L2 between the plurality of first regions R1. When the first horizontal distance L1 from a side of the carrier 100 to the first region R1 is smaller than the second horizontal distance L2 between the plurality of first regions R1, the first region R1 may be sufficiently surrounded by the second region R2, after sawing the carrier 100, and accordingly, it may be easier to handle the sub-panel SP.

The first and second horizontal distances L1 and L2 may mean distances extending parallel to a first horizontal direction, a second horizontal direction (X direction, Y direction) and/or a diagonal direction.

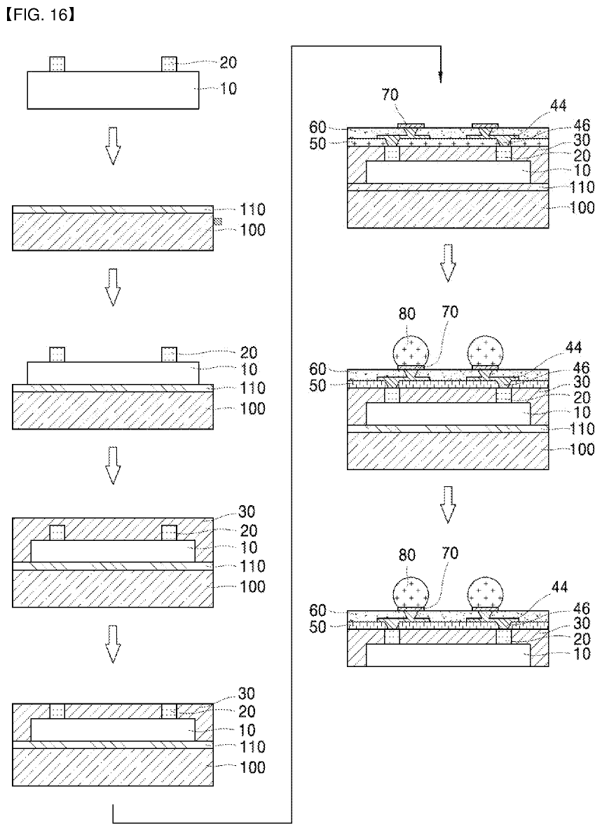

FIG. 14 is a layout view of a semiconductor package according to embodiments of the present invention.

Referring to FIG. 14, The semiconductor package 2d may have a structure in which the dummy die 12 forms two rows and columns inside the first region R1. For example, the number of rows and columns in which the dummy die 12 is disposed is not limited thereto. For example, the dummy die 12 may be disposed in three or more rows and/or columns inside the first region R1.

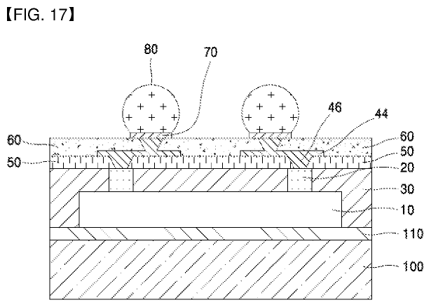

FIG. 15 is a layout view of a semiconductor package according to embodiments of the present invention.

Referring to FIG. 15, in a planar view, the dummy die 12 of the semiconductor package 2e may surround the die 10. Since the dummy die 12 is disposed on the first region R1, the dummy die 12 may be disposed on the carrier 100 even after the first sawing. The dummy die 12 may be removed after the second sawing.

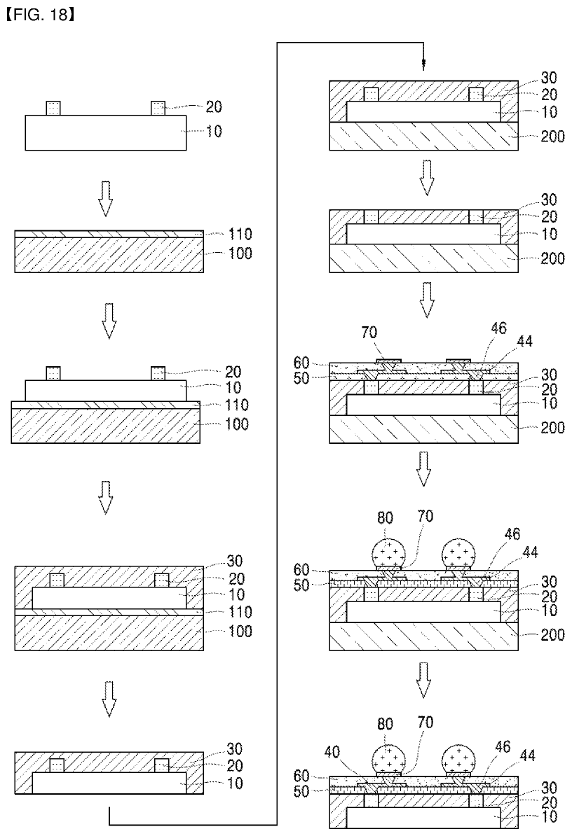

FIG. 16 is a cross-sectional view showing a progress of a semiconductor package manufacturing method according to embodiments of the present invention. FIG. 17 is a cross-sectional view illustrating a cross-section of a semiconductor package just before a detach process of the carrier 100 and the adhesive layer 110 is performed in a process of manufacturing a semiconductor package according to embodiments of the present invention. In more detail, each step of the method of manufacturing a semiconductor package according to embodiments of the present invention will be described below in detail.

Referring to FIGS. 16 and 17, a post 20 may be formed on the upper surface of a die 10. The post 20 of the present embodiment is formed on the die 10 and may be a copper stud bump.

Subsequently, a step of forming an adhesive layer 110 on the carrier 100 is performed. Next, a step of disposing a die 10 on which a post 20, is formed on the adhesive layer 110 is performed. The die 10 is mounted on the carrier 100.

Next, a step of molding a semiconductor package is performed (Front-Mold). In this step, the die 10 disposed on an upper side of the carrier 100 is molded by the molding layer 30. That is, the die 10 and the post 20 disposed on the adhesive layer 110 are molded by the molding layer 30. At this time, the molding layer 30 may include epoxy resin.

Next, a step of grinding a top side of the semiconductor package to expose the post 20 disposed on the die 10 is performed (Co-grind). Through this step, an upper surface of the post 20 is exposed, and the post 20 can be electrically connected to the redistributed line 44 and the conductive via 46 through the exposed upper surface.

Next, a step of forming a redistributed line 44, a conductive via 46, and an insulating layer 50 on the upper surface of the semiconductor package is performed. In this step, the redistributed line 44 and the conductive via 46 may be formed on the insulating layer 50. The insulating layer 50 may be made of a resin coated film (RCF). In addition, an under bump metallurgy (UBM) layer 70 may be formed on an upper portion of the redistributed line 44 and the conductive via 46. The UBM layer 70 may be electrically connected to the redistributed line 44 and the conductive via 46. The UBM layer 70 may be formed on a passivation layer 60 formed on an upper portion of the insulating layer 50. Through this step, a redistributed line 44 and a conductive via 46 disposed on an insulating layer 50 and a UBM layer 70 disposed on the passivation layer 60 are formed (RCF-UBM).

After this, a step of disposing an electrical connection member 80 on the UBM layer 70 is performed. The electrical connection member 80 may be formed in a ball shape (Ball mount).

Finally, a detach step of removing a carrier 100 and an adhesive layer 110 from the lower surface of the semiconductor package is performed. The carrier 100 and the adhesive layer 110 may be removed by applying heat.

Meanwhile, in this embodiment, the second sawing process for separating the semiconductor package into individual die units may be performed before or after removing the carrier 100 and the adhesive layer 110.

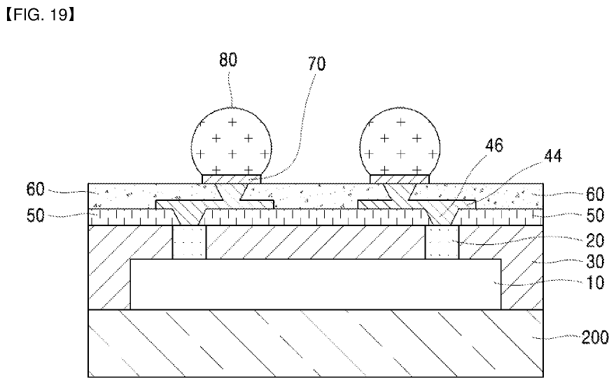

FIG. 18 is a cross-sectional view showing the progress of a semiconductor package manufacturing method according to embodiments of the present invention. FIG. 19 is a cross-sectional view showing a cross-section of a semiconductor package immediately before a back grinding process is performed during a process of manufacturing a semiconductor package according to embodiments of the present invention In more detail, each step of the semiconductor package manufacturing method according to embodiments of the present invention will be

Referring to FIGS. 18 and 19, a post 20 may be formed on the upper surface of a die 10. The post 20 of the present embodiment is formed on the die 10 and may be a copper stud bump.

Subsequently, a step of forming an adhesive layer 110 on a carrier 100 is performed. Next, a step of disposing a die 10 on which a post 20 is formed on the adhesive layer 110 is performed. The die 10 is mounted on the carrier 100.

Next, a step of molding a semiconductor package is performed (Front-Mold). In this step, the die 10 disposed on an upper portion of the carrier 100 is molded by the molding layer 30. That is, the die 10 and the post 20 disposed on the adhesive layer 110 are molded by the molding layer 30. At this time, the molding layer 30 may include an epoxy resin.

Next, a step of removing the carrier 100 is performed (Carrier De-bond). In this step, a lower surface of the semiconductor package is exposed as the carrier 100 is removed. Accordingly, a lower surface of the die 10 is also exposed. However, an upper surface and a side surface of the die 10 on which the post 20 is formed are not exposed because the upper surface and the side surface of the die 10 are molded by the molding layer 30.

Next, a step of forming a lamination layer 200 on a lower surface of the semiconductor package from which the carrier 100 is removed is performed. For example, the lamination layer 200 may be formed by attaching a BSP lamination film.

Next, a step of exposing the post 20 on the die 10 is performed by performing top grinding on a top side of the semiconductor package (Co-grind). Through this step, an upper surface of the post 20 is exposed, and the post 20 can be electrically connected to the redistributed line 44 and the conductive via 46 through the exposed upper surface.

Next, a step of forming the redistributed line 44, the conductive via 46, and the insulating layer 50 on the upper surface of the semiconductor package is performed. In this step, the redistributed line 44 and the conductive via 46 can be formed on the insulating layer 50. The insulating layer 50 can be made of RCF (Resin Coated Film). In addition, a passivation layer 60 and an Under Bump Metallurgy (UBM) layer 70 may be formed on the upper portion of the redistributed line 44, the conductive via 46, and the insulating layer 50. The UBM layer 70 may be electrically connected to the redistributed line 44 and the conductive via 46. The UBM layer 70 may be formed on the passivation layer 60 formed on the upper portion of the insulating layer 50. Through this step, the redistributed line 44 and the conductive via 46 disposed on the insulating layer 50, and the UBM layer 70 disposed on the passivation layer 60 are formed (RCF-UBM).

Thereafter, a step of disposing an electrical connection member 80 on the UBM layer 70 is performed. The electrical connection member 80 may be formed in a ball shape (Ball mount).

Finally, a step of removing the lamination layer 200 from a lower surface of the semiconductor package is performed. The lamination layer 200 can be removed by grinding the lower surface of the semiconductor package (Back-grind).

Meanwhile, in this embodiment, a second sawing process for separating the semiconductor package into individual die units may be performed before or after removing the lamination layer 200.

1. A semiconductor package manufacturing method comprising:
a step of disposing a plurality of dies on a carrier while being spaced apart from each other in a horizontal direction;
a first sawing step of sawing the carrier to separate the carrier into a plurality of sub-panels on which the plurality of dies are disposed;
a step of testing the dies; and
a second sawing step of sawing between each of the dies of the sub-panels to separate the sub-panels into individual semiconductor packages;
wherein the carrier includes a plurality of first regions in which the dies are disposed and a second region in which the dies are not disposed, and
wherein a first horizontal distance from a side of the carrier to the first region closest to the side is smaller than a second horizontal distance from two first regions closest to each other among the plurality of first regions.

2. The semiconductor package manufacturing method of claim 1, wherein the first sawing step is performed by sawing along a first scribe lane provided in the second region.

3. The semiconductor package manufacturing method of claim 2, wherein the first horizontal distance from the side of the carrier to the first region is smaller than a third horizontal distance from the first region to a side of the sub-panel relatively close to the first scribe lane.

4. The semiconductor package manufacturing method of claim 1, wherein, when viewed from a planar perspective, the sub-panel has the first region surrounded by the second region.

5. The semiconductor package manufacturing method of claim 1, wherein the carrier is divided into the plurality of sub-panels, and
wherein at least two of the plurality of sub-panels have different horizontal areas.

6. A semiconductor package comprising:
a carrier;
an adhesive layer disposed on the carrier; and
a plurality of dies disposed on the adhesive layer and bonded by the adhesive layer; and
wherein the carrier includes a plurality of first regions in which the dies are disposed and a second region in which the dies are not disposed, and
wherein a horizontal distance from a side of the carrier to the first region closest to the side is smaller than a horizontal distance from two first regions closest to each other among the plurality of first regions.

7. The semiconductor package of claim 6, wherein a first scribe lane in which the carrier is sawed is provided in the second region.

8. The semiconductor package of claim 6, wherein, when viewed from a planar perspective, the first region is surrounded by the second region.

9. A semiconductor package manufacturing method comprising:
a step of disposing a plurality of dies and dummy dies on a carrier while being spaced apart from each other;
a first sawing step of sawing the carrier to separate the carrier into sub-panels on which the plurality of dies and dummy dies are disposed;
a step of testing the dies; and
a second sawing step of sawing between each die of the sub-panels to separate the sub-panels into individual semiconductor packages; and,
wherein the carrier includes a plurality of first regions in which the die is disposed and second regions in which the die is not disposed, and
wherein the dummy dies are disposed adjacent to a side of the first region.

10. The semiconductor package manufacturing method of claim 9, wherein a horizontal area of the dummy die is different from a horizontal area of the die.

11. The semiconductor package manufacturing method of claim 9, wherein, when viewed from a planar perspective, the dummy dies surround the dies inside the sub-panel and are disposed along at least one side of the sub-panel.

12. The semiconductor package manufacturing method of claim 9, wherein the dummy dies are disposed along a side of the carrier.

13. The semiconductor package manufacturing method of claim 9, wherein the dummy dies are disposed inside the sub-panel to form one or more rows or columns.

14. A semiconductor package comprising:
a carrier;
an adhesive layer disposed on the carrier; and
a plurality of dies and dummy dies disposed on the adhesive layer and bonded by the adhesive layer; and
wherein the carrier includes a plurality of first regions in which the dies and dummy dies are disposed and a second region in which the dies are not disposed, and
wherein the dummy dies are disposed adjacent to at least one side of the first region.

15. The semiconductor package of claim 14, wherein, when viewed from a planar perspective, the second region surrounds the first region inside the sub-panel, and the dummy dies are disposed along a side of the carrier.

16. The semiconductor package of claim 14, wherein, when viewed from a planar perspective, the dummy dies are disposed along at least two sides of the first region inside the first region.
